(19) United States
(12) Patent Application Publication
(10) Pub. No.: US 2012/0137972 A1
(43) Pub. Date: Jun. 7, 2012

(54) FILM FORMING APPARATUS

(75) Inventor: Hidehiro YASUKAWA, Kawasaki-shi (JP)

(73) Assignee: CANON ANELVA CORPORATION, Kawasaki-shi (JP)

(21) Appl. No.: 13/305,904

(22) Filed: Nov. 29, 2011

(30) Foreign Application Priority Data
Dec. 7, 2010 (JP) 2010-272096

(51) Int. Cl. B05C 11/00; B05C 13/00

(52) U.S. Cl. 118/712

(57) ABSTRACT

A film forming apparatus which forms a film on a long substrate includes a film forming unit, a transport unit which transports the long substrate, a supply portion which supplies an inspection substrate onto the long substrate, and a substrate recovery portion which recovers the inspection substrate that was placed on the long substrate and that has a film formed thereon by the film forming unit.

### BACKGROUND OF THE INVENTION

1. Field of the Invention

The present invention relates to a film forming apparatus which forms a film on a long substrate.

2. Description of the Related Art

When a thin film is formed by, for example, sputtering or deposition, the film physical properties such as the thin film sheet resistance are measured to control the quality of the formed film (for example, Japanese Patent Laid-Open No. 11-302844).

Japanese Patent Laid-Open No. 11-302844 describes a technique in which after a substrate having a metal thin film formed on it is unloaded from a vacuum chamber, the sheet resistance of the substrate is measured. This patent literature also describes a technique in which after a sheet resistance monitoring substrate is attached on a substrate holder, together with a substrate, and a film is formed on the substrate, the sheet resistance of the monitoring substrate is measured.

On the other hand, a film forming apparatus which forms a film by, for example, sputtering or deposition is also employed to manufacture, for example, a solar cell, a secondary cell, or a functional film, and a long substrate is often employed as a processing substrate to improve the productivity. The so-called roll-to-roll scheme is generally adopted to process a long substrate. In this scheme, a series of operations of unwinding a long substrate from a roll, stretching it, performing a necessary process, and winding it into a roll again is performed in a single apparatus. A long substrate is also called a web, and its material and thickness vary depending on the purpose of use.

When a film is formed on a long substrate, unwinding and winding operations must be performed in a vacuum chamber. In addition, when a long substrate wound into a roll is unwound and stretched, its length sometimes reaches 1,000 m or more although it normally varies depending on the purpose of use, so the processing time is very long.

Therefore, the method as described in Japanese Patent Laid-Open No. 11-302844 is not applicable to a film forming apparatus which uses the roll-to-roll scheme.

As a known method of measuring the sheet resistance by a film forming apparatus which uses the roll-to-roll scheme, the sheet resistance of a film substrate is measured in a vacuum chamber (for example, FIG. 1 in Japanese Patent Laid-Open No. 1-283357).

Unfortunately, in the method as described in Japanese Patent Laid-Open No. 1-283357, when a multilayer film is formed using a plurality of film forming units, the physical properties of the entire multilayer film are naturally measured, and this means that the physical properties of a specific film cannot be measured.

Also, even if a monolayer film is to be formed on the web, the use of a conductive substrate such as stainless steel, aluminum, or copper as the web material makes it impossible to measure the sheet resistance of a material deposited on the web by sputtering. That is, the sheet resistance can be measured by supplying a current to a member including a web material and a film formed on it, and measuring the sheet resistance based on the difference in potential between two points on the member, but when the web material is a conductive material, the current for measurement passes through both the web material and the film formed by the film forming unit, thus making it impossible to obtain the difference in potential between two points on the formed film.

### SUMMARY OF THE INVENTION

The present invention provides a film forming apparatus which uses the roll-to-roll scheme advantageous in easily measuring the film physical properties regardless of the type of long substrate used.

One of the aspects of the present invention provides a film forming apparatus which forms a film on a long substrate, the apparatus comprising: a film forming unit; a transport unit which transports the long substrate; a supply portion which supplies an inspection substrate onto the long substrate; and a substrate recovery portion which recovers the inspection substrate that was placed on the long substrate and that has a film formed thereon by the film forming unit.

The present invention makes it possible to inspect an arbitrary film forming state without interrupting production.

The present invention is also advantageous in inspecting the film forming performance of a specific layer even if a multilayer film is stacked on a long substrate.

The present invention is moreover advantageous in inspecting the film properties such as the sheet resistance even if a film is formed on a conductive web, which can conventionally hardly be used as a material on which a film is formed.

The present invention is again advantageous in reducing the frequency of occurrence of a product defect upon loading an inspection substrate.

Further features of the present invention will become apparent from the following description of exemplary embodiments with reference to the attached drawings.

### BRIEF DESCRIPTION OF THE DRAWINGS

FIG. 1 is a schematic side view of a film forming apparatus according to an embodiment of the present invention;

FIG. 2 is a schematic side view of a substrate supply portion;

FIG. 3 is a schematic side view of a substrate recovery portion; and

FIG. 4 is a schematic side view of a film forming apparatus according to another embodiment of the present invention.

### DESCRIPTION OF THE EMBODIMENTS

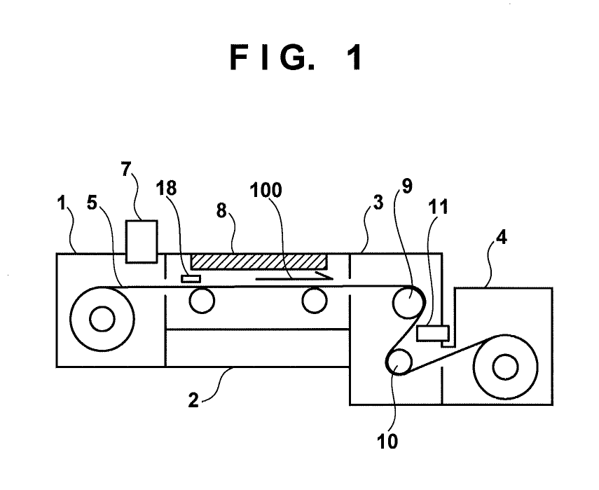

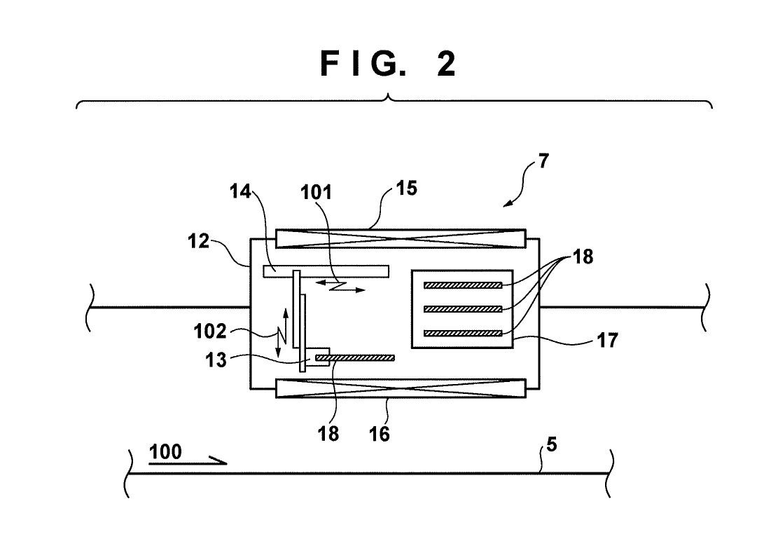

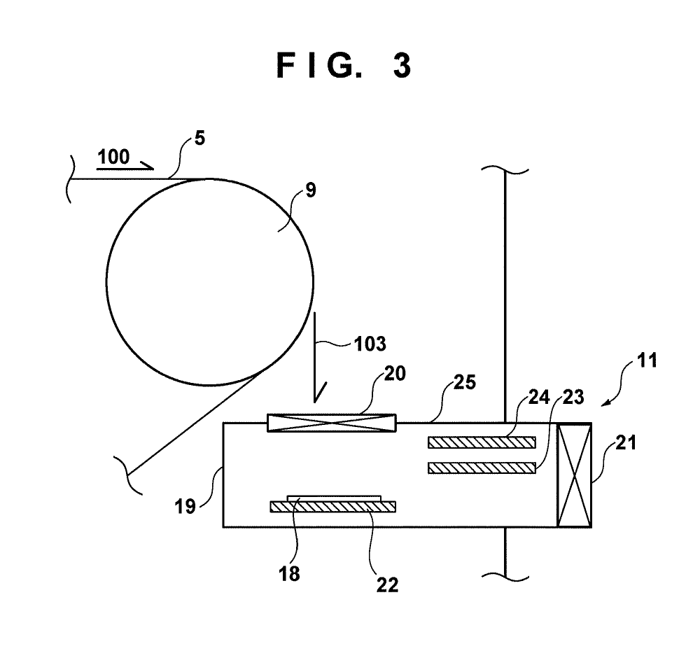

Embodiments of the present invention will be described below. FIG. 1 is a schematic side view of the entire film forming apparatus according to an embodiment of the present invention. FIG. 2 is a schematic side view of a substrate loading portion, and FIG. 3 is a schematic side view of a substrate recovery portion.

A mode of a film forming apparatus according to the present invention will be described below with reference to FIGS. 1 to 3.

Referring to FIGS. 1 to 3, the configurations, sizes, arrangements, and numbers of parts constituting the apparatus, for example, are not intended to limit the present invention. The film forming apparatus to be described hereinafter merely provides an example to facilitate understanding of the film forming apparatus according to the present invention, and this example can be changed and modified without departing from the scope of the present invention.

A vacuum chamber 1 includes an unwinding mechanism for unwinding a web 5 serving as a long substrate from a roll. A vacuum chamber 2 includes a film forming unit for forming a film by, for example, sputtering. A vacuum chamber 3 includes a substrate recovery portion for recovering an inspection substrate. A vacuum chamber 4 includes a winding mechanism for winding the web 5 into a roll.

Each of the vacuum chambers 1, 2, 3, and 4 is provided with an opening for transporting the web 5, and a roller serving as a transport unit for transporting the web 5. The web 5 is transported via the openings in adjacent vacuum chambers. The vacuum chamber 1 is provided with a substrate supply portion 7 including a mechanism which supplies an inspection substrate 18 into the vacuum chamber 1.

The substrate supply portion 7 is connected to the vacuum chamber 1 so as to supply the inspection substrate 18 to the position through which the web 5 before a film forming process passes. More specifically, the substrate supply portion 7 is configured to supply the inspection substrate 18 onto the web 5 at that position. The vacuum chamber 3 is provided with a substrate recovery portion 11 including a mechanism for recovering the inspection substrate 18. The vacuum chamber 3 is also provided with a first roller 9, and a second roller 10 provided below the first roller 9.

An exhaust mechanism (not shown) is connected to each vacuum chamber, and can change the pressure in this vacuum chamber from the atmospheric pressure to the vacuum pressure. Similarly, a gas supply mechanism (not shown) is connected to each vacuum chamber, and can restore the pressure in this vacuum chamber to the atmospheric pressure using air or an inert gas such as nitrogen.

A target 8 is placed in the vacuum chamber 2 including the film forming unit, is electrically insulated from the vacuum chamber 2 by an insulating component (not shown), and is connected to a power supply (not shown). A film is formed on the web 5 in the vicinity of the target 8. The number and types of targets 8 can be changed in accordance with the process conditions and the properties of a multilayer film to be formed.

A gas line (not shown) is connected to the vacuum chamber 2 for sputtering, separately from the gas supply mechanism for restoring the pressure in the vacuum chamber 2 to the atmospheric pressure. The gas line is used to supply an inert gas for sputtering to the vacuum chamber 2.

The rollers 9 and 10 and a roller group serving as a transport mechanism for the vacuum chambers 1, 2, 3, and 4 are accurately fixed in position by a frame (not shown), and can smoothly rotate to transport the web 5. A driving mechanism (not shown) is connected to these rollers as needed in accordance with the types and functions of rollers, and can rotate these rollers.

Also, by unwinding and winding the web 5 from and into a roll while controlling the tension of the web 5 by a tension sensor (not shown), the orientation of the web 5 at the time of sputtering can be appropriately maintained while preventing troubles upon transportation of the web 5. The rollers rotated by the driving mechanism transport the web 5 in a direction 100 in which the web 5 travels.

A mode of the substrate supply portion 7 will be described with reference to FIG. 2. The same reference numerals as in FIG. 1 denote the same or equivalent parts in FIG. 2. The substrate supply portion 7 includes a vacuum chamber 12, a first gate valve 15 provided to the vacuum chamber 12 on the atmospheric side, and a second gate valve 16 provided to the vacuum chamber 12 on the side of the vacuum chamber 1. Providing the first gate valve 15 and second gate valve 16 makes it possible to change the pressure in the substrate supply portion 7 to the atmospheric pressure or vacuum pressure, independently of the pressure in the vacuum chamber 1.

The pressure in the substrate supply portion 7 can be changed using the exhaust mechanism and gas supply mechanism (neither is shown). The first gate valve 15 and second gate valve 16 can open/close openings large enough to pass the inspection substrate 18.

As the inspection substrate 18, a substrate suitable, after it is recovered, for measuring the physical properties of the film that was formed thereon can be used. When the sheet resistance, for example, is measured as the film physical property, a nonconductive substrate such as a glass substrate can be used as the inspection substrate 18. The number of inspection substrates 18 that can be supplied into the vacuum chamber 12 may be one or plural, and is not particularly limited. However, as shown in FIG. 2, a method of placing a cassette 17, which mounts a plurality of inspection substrates 18, in the vacuum chamber 12 via the first gate valve 15 is advantageous in loading the inspection substrate 18 into the vacuum chamber 12 in a short period of time.

An inspection substrate transport mechanism is disposed in the vacuum chamber 12. The inspection substrate transport mechanism includes a hand 13 for loading the inspection substrate 18 into the vacuum chamber 1, and a hand driving unit 14. The hand driving unit 14 can drive the hand 13 in a direction 101 in which the inspection substrate 18 is picked up, and a direction 102 in which the inspection substrate 18 is loaded. Hence, the hand driving unit 14 can pick up the inspection substrate 18 from the cassette 17, and brings it close to the surface of the web 5, so that the inspection substrate 18 falls onto the web 5 from a close range.

A method of loading the inspection substrate 18 into the film forming apparatus will be described next. In this example, the inspection substrate 18 is loaded into the vacuum chamber 1 of the film forming apparatus. The inspection substrate 18 is loaded into the vacuum chamber 1 while the pressure in the vacuum chamber 12 is maintained at the vacuum pressure, and the film forming apparatus is ready to sputter.

While the second gate valve 16 is open, and the inspection substrate 18 is gripped by the hand 13, the hand driving unit 14 drives the hand 13 in the direction 102 in which the inspection substrate 18 is loaded, and cancels gripping of the inspection substrate 18 by the hand 13 in the vicinity of the surface of the web 5, so that the inspection substrate 18 falls onto the web 5.

The inspection substrate 18 has a very short distance to the surface of the web 5, but preferably has blunt corners because IL freely falls.

The fallen inspection substrate 18 reaches the position, at which a sputtering process is executed, upon traveling in the direction 100 in which the web 5 travels.

The sputtering process can be controlled so that a material to be inspected is formed on the inspection substrate 18, at the timing at which the inspection substrate 18 reaches that position. When, for example, a plurality of materials are stacked on the web 5 by multilayer sputtering, the individual materials often require inspection. In this case, only a material to be inspected is formed on each inspection substrate 18.

A mode of the substrate recovery portion 11 shown in FIG. 1 will be described with reference to FIG. 3. The same reference numerals as in FIG. 1 denote the same or equivalent parts in FIG. 3. The substrate recovery portion 11 includes a vacuum chamber 19, a third gate valve 20 provided to the vacuum chamber 19 at a position that falls within the vacuum chamber 3, and a fourth gate valve 21 provided to the vacuum chamber 19 at a position on the atmospheric side. A substrate recovery tray 22 for recovering the inspection substrate 18 is provided in the vacuum chamber 19.

A method of recovering the inspection substrate 18 having undergone a sputtering process will be described next. The direction in which the web 5 travels is changed by winding the web 5 on the first roller 9 at a position above the substrate recovery portion 11. Before the web 5 reaches the first roller 9, the web 5 horizontally moves in the direction 100 in which it travels, so the inspection substrate 18 can continue to be present on the web 5. However, after the inspection substrate 18 passes through the first roller 9, it falls by its self weight in a direction 103 in which it falls. At the destination to which the inspection substrate 18 falls, the vacuum chamber 19 stands by to receive the fallen inspection substrate 18 while the third gate valve 20 is open.

The distance by which the inspection substrate 18 falls is desirably minimized. At the same time, to absorb a shock that results in damage to the inspection substrate 18 upon falling, an elastic material such as an elastomer having an appropriate thickness is desirably disposed on the surface of the substrate recovery tray, that is, first recovery tray 22.

To recover a plurality of inspection substrates 18, a plurality of trays including a second recovery tray 23 and third recovery tray 24 may be placed in the vacuum chamber 19.

To recover a plurality of inspection substrates 18, it is necessary to mount a moving mechanism (not shown) which drives the first recovery tray 22, second recovery tray 23, and third recovery tray 24 to move only a tray standing by for recovery to the position to which the inspection substrate 18 falls.

After the operation of recovering the inspection substrate 18 using the substrate recovery tray 22 is completed, the third gate valve 20 is closed, the pressure in the vacuum chamber 19 is changed to the atmospheric pressure using air or an inert gas such as nitrogen by the gas supply mechanism (not shown), and the fourth gate valve 21 is opened, thereby unloading the inspection substrate 18. The film physical properties such as the sheet resistance of the unloaded substrate are measured by an arbitrary measuring unit.

The apparatus according to this mode can measure the physical properties of a formed film without interrupting a film forming process. Also, this apparatus can measure the sheet resistance of a formed film even if a conductive substrate such as aluminum or copper is used as a long substrate.

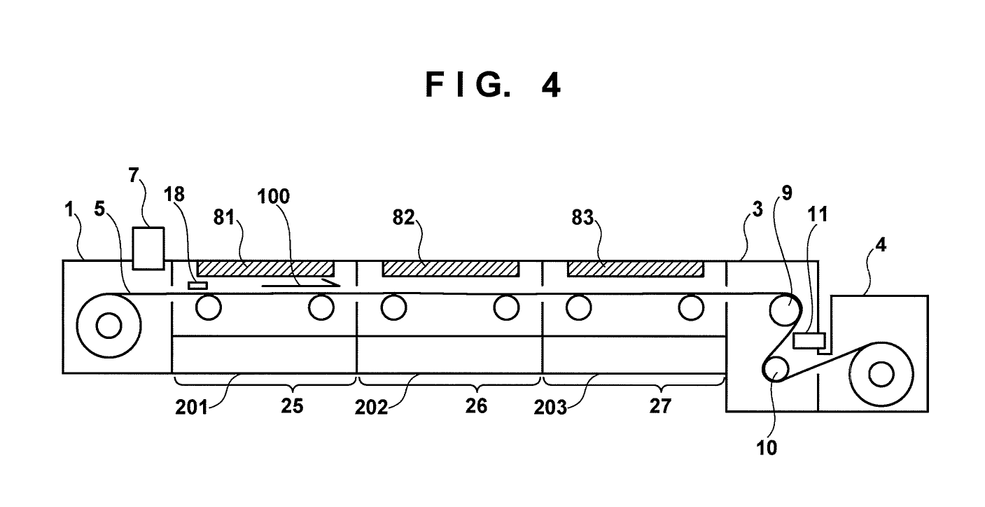

Another mode of the film forming apparatus according to the present invention will be described with reference to FIG. 4. This mode is basically the same as the above-mentioned embodiment except that in the former the film forming apparatus includes a plurality of film forming units. The same reference numerals as in FIG. 1 denote the same or equivalent parts in FIG. 4. According to this mode, films can be stacked in three layers, and the physical properties of each layer can be measured using an inspection substrate.

A method of measuring an arbitrary film among a plurality of stacked films will be described with reference to FIG. 4. A film forming process is continuously performed on a long substrate. Hence, normally, after a film is formed by a first film forming process 25, a second film forming process 26 and a third film forming process 27 are directly performed to stack a plurality of films.

Targets 81, 82, and 83 are placed in vacuum chambers 201, 202, and 203, respectively. Only one arbitrary film cannot be formed even if an inspection substrate 18 is loaded into the vacuum chambers 201, 202, and 203 by a substrate supply portion 7 in this state.

Therefore, a controller (not shown) must control each function in synchronism with the timing at which the inspection substrate 18 is loaded, using a selection mechanism capable of forming one arbitrary film. A detailed method of forming a single film on the inspection substrate 18 by the third film forming process 27, and unloading the inspection substrate 18 will be described below.

First, the controller (not shown) issues an instruction to the substrate supply portion 7 to inspect the third film forming process 27. The substrate supply portion 7 drops the inspection substrate 18 onto a web 5. At this time, the inspection substrate 18 travels in a direction 100 in which the web 5 travels, and eventually reaches the first film forming process 25.

The controller causes a transport control unit (not shown) to control travel of the web 5 based on, for example, the transport speed of the web 5, thereby determining whether the inspection substrate 18 has reached the first film forming process 25. More specifically, the controller stores the distance from the position to which the inspection substrate 18 falls to the position at which the first film forming process 25 starts, thereby determining whether the inspection substrate 18 has reached the first film forming process 25, based on the transport speed and the elapsed time after falling.

Before the inspection substrate 18 reaches the first film forming process 25, power supply to a target 80 placed in the first film forming process 25 stops. In other words, a film forming process stops.

After the inspection substrate 18 passes through the region, in which the first film forming process 25 is performed, upon traveling in the direction 100 in which the web 5 travels, power supply to the target 80 placed in the first film forming process 25 is started again to restart forming a film.

Since passage of the inspection substrate 18 can be determined based on the characteristics associated with the first film forming process 25 and the speed control of the apparatus controller mentioned above, special monitoring is unnecessary. Nevertheless, to ensure higher reliability, passage control of the inspection substrate 18 may be done using a sensor.

Similarly, the inspection substrate 18 can pass through the region, in which the second film forming process 26 is performed, without forming a film on it.

After the inspection substrate 18 reaches the third film forming process 27, a film is directly formed. Thus, an inspection substrate 18 having a film formed on it only in the region in which the third film forming process 27 is performed is fabricated. Then, a substrate recovery portion 11 is used to recover the inspection substrate 18, as described with reference to FIG. 3.

In the above-mentioned method, a plurality of films are not formed on the portion of the surface of the web 5, where the inspection substrate 18 is mounted, in the regions in which the film forming processes 25 to 27 are performed. Hence, only this portion does not become a final product. This lowers the throughput albeit slightly, and wastes the web 5.

However, when an arbitrary film forming process is inspected upon replacing the web 5 with an inspection web simply for inspection, the throughput lowers to a larger extent, and an inspection web is additionally necessary. That is, no product is manufactured while the web 5 is replaced with an inspection web. Similarly, no product is manufactured either, while the inspection web with which the web 5 is replaced for inspection is removed.

Although the above description assumes that a single film forming apparatus loads the inspection substrate 18 in one portion and recovers it in one portion, dedicated substrate loading and substrate recovery portions may be disposed in each film forming chamber.

In this case, it is necessary to add, for example, a robot hand to the substrate recovery mechanism, but nonetheless an advantage can be provided because the portion which does not become a product is limited to the vicinity of the inspection substrate 18.

Although the film forming unit uses a sputtering unit in the above-mentioned example, it is not limited to a sputtering unit, and may use, for example, a CVD unit.

A film forming process for each roll is assumed in a roll-to-roll film forming apparatus, and therefore is not interrupted unless an interruption factor such as trouble occurs. However, according to the present invention, an arbitrary film forming process can be inspected without interrupting production.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-272096, filed Dec. 7, 2010, which is hereby incorporated by reference herein in its entirety.

What is claimed is:

1. A film forming apparatus which forms a film on a long substrate, the apparatus comprising:
a film forming unit;
a transport unit which transports the long substrate;
a supply portion which supplies an inspection substrate onto the long substrate; and
a substrate recovery portion which recovers the inspection substrate that was placed on the long substrate and that has a film formed thereon by the film forming unit.

2. The apparatus according to claim 1, wherein the long substrate is a conductive substrate.

3. The apparatus according to claim 1, comprising a plurality of film forming units including said film forming unit.

4. The apparatus according to claim 3, wherein the plurality of film forming units are controlled so that a film is formed on the inspection substrate by one film forming unit selected from the plurality of film forming units.

5. The apparatus according to claim 1, wherein the transport unit is configured to transport the long substrate by a roll-to-roll scheme, and the recovery portion recovers the inspection substrate fallen by a self weight thereof.
